(19) United States
(12) Patent Application Publication
(10) Pub. No.: US 2008/0032512 A1
(43) Pub. Date: Feb. 7, 2008

(54) METHOD FORMING SILICON OXYNITRIDE GATE DIELECTRIC LAYER WITH UNIFORM NITROGEN CONCENTRATION

(75) Inventors: Dong-Chan KIM, Gyeonggi-do (KR); Seong-Hoon JEONG, Gyeongsangnam-do (KR); Myoung-Bum LEE, Seoul (KR); Sang-Bom KANG, Seoul (KR); Jin-Hwa HEO, Gyeonggi-do (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Gyeonggi-do (KR)

(21) Appl. No.: 11/828,541

(22) Filed: Jul. 26, 2007

(30) Foreign Application Priority Data
Aug. 2, 2006 (KR) 10-2006-0073057

(51) Int. Cl. H01L 21/31

(52) U.S. Cl. 438/771; 257/E21.24

(57) ABSTRACT

A method of manufacturing a semiconductor device in a process camber is disclosed. The method includes forming a preliminary dielectric layer including oxynitride on a substrate by performing a plasma oxidation treatment and a first plasma nitridation treatment, wherein the preliminary dielectric layer has a substantially uniform nitrogen concentration profile to a defined depth, and forming a dielectric layer from the preliminary dielectric layer by performing a second plasma nitridation treatment, wherein the nitrogen concentration of the dielectric layer is higher than that of the preliminary dielectric layer.

### CROSS-REFERENCE TO RELATED APPLICATIONS

This application claims priority under 35 U.S.C. § 119 to Korean Patent Application No. 10-2006-0073057 filed Aug. 2, 2006, the subject matter of which is hereby incorporated by reference.

### BACKGROUND OF THE INVENTION

1. Field of the Invention

The present invention relates to a method of manufacturing a semiconductor device. More particularly, the invention relates to a method of manufacturing a gate dielectric layer in a semiconductor device.

2. Description of the Related Art

Contemporary memory devices, such as dynamic random access memory (DRAM) devices, are fabricated on a semiconductor substrate (e.g., a silicon wafer) and include an enormous number of unit memory cells arranged in an addressable array. Each unit cell typically includes a transistor and a capacitor. The unit cell transistor includes a gate structure formed on the substrate proximate source/drain regions formed in the substrate. The capacitor typically includes a lower electrode electrically connected to one of the source/drain regions, and an upper electrode separated from the lower electrode by a dielectric layer.

With increasing integration densities, the nominal size of unit cells has rapidly decreased. Various problems are associated with this reduction in unit cell size. For example, as the size of the unit cell decreases, short channel effects may occur because the constituent channel length of the unit cell transistor decreases. Additionally, narrow channel effect (or narrow channel width effects) may occur because the effective channel width of the transistor decreases. Furthermore, other operational characteristics, such as a carrier mobility within the transistor, overall current driving capability, etc., may be adversely impacted by reduction in the size of the transistor.

The gate electrode of the unit cell transistor in conventional memory devices is usually formed from a polysilicon material doped with selected impurities. The gate dielectric layer of the transistor is commonly implemented as a silicon oxide layer which is usually formed by performing a thermal oxidation process on the substrate.

A thickness of the gate dielectric layer must be reduced to improve integration density (i.e., form a smaller unit cell). Unfortunately, reduction in the thickness of the gate dielectric layer affects the reliability and operating speed of the transistor. That is, as the thickness of the gate dielectric layer is reduced, leakage current through the gate dielectric layer may increase. Accordingly, the semiconductor device consumes more power and generates more heat within the semiconductor device. These results tend to decreases the overall performance reliability of the semiconductor device. Additionally, the impurities doped into the polysilicon forming the gate electrode may diffuse into the channel region of the substrate, thereby decreasing the reliability of the semiconductor device.

In order to address these problems, a method of forming a silicon oxynitride layer by nitrating a silicon oxide layer that serves as the gate insulation layer has been proposed. The silicon oxynitride layer reduces the leakage current and prevents diffusion of impurities forming the gate electrode into the channel region. Additionally, electron mobility within the semiconductor device may be increased, and thus the operating speed of the semiconductor device may be improved by incorporating this typb of layer.

When the silicon oxide layer serving as a unit cell dielectric layer is nitrated, nitrogen is implanted primarily in an upper portion of the silicon oxide layer. This results in a non-uniform nitrogen concentration profile down through the resulting silicon oxynitride layer. This upper portion concentration asymmetry of the silicon oxynitride layer may also limit the overall nitrogen concentration in this type of layer.

### SUMMARY OF THE INVENTION

Embodiments of the invention provide a method of manufacturing a semiconductor device having a gate dielectric layer with a more uniform and more densely doped nitrogen concentration.

In one embodiment, the invention provides a method of manufacturing a semiconductor device in a process camber, the method comprising; forming a preliminary dielectric layer including oxynitride on a substrate by performing a plasma oxidation treatment and a first plasma nitridation treatment, wherein the preliminary dielectric layer has a substantially uniform nitrogen concentration profile to a defined depth, and forming a dielectric layer from the preliminary dielectric layer by performing a second plasma nitridation treatment, wherein the nitrogen concentration of the dielectric layer is higher than that of the preliminary dielectric layer.

### BRIEF DESCRIPTION OF THE DRAWINGS

FIGS. (FIGS.) 1, 4, 6 and 7 are cross-sectional views illustrating a DRAM device in accordance with various embodiments of the invention;

FIG. 2 is a graph illustrating a nitrogen concentration profile in a silicon oxynitride layer formed by a plasma oxidization treatment and an in-situ first plasma nitridation treatment;

FIG. 3 is a graph illustrating a nitrogen concentration profile in a silicon oxynitride layer formed by a plasma oxidization treatment and an in-situ first plasma nitridation treatment using a bias voltage;

FIG. 5 is a graph illustrating concentration profiles of nitrogen and oxygen in a preliminary dielectric layer and a gate dielectric layer;

FIG. 8 is a graph comparing gate leakage currents for a conventional gate dielectric layer and a gate dielectric layer formed in accordance with an example embodiment of the invention;

FIG. 9 is a graph comparing transconductances of semiconductor devices including a conventional gate dielectric layer and a gate dielectric layer formed in accordance with an example embodiment of the invention;

FIGS. 10 and 11 are graphs comparing ON-currents versus OFF-currents for a conventional semiconductor device and a semiconductor device formed in accordance with an example embodiment of the invention; and

FIG. 12 is a graph comparing the density of interface trap (DIT) of a conventional semiconductor device and a semiconductor device formed in accordance with an example embodiment of the invention.

### DESCRIPTION OF THE EMBODIMENTS

Embodiments of the invention will now be described in some additional detail with reference to the accompanying drawings. The invention may, however, be embodied in many different forms and should not be construed as being limited to the illustrated embodiments. Rather, these embodiments are presented as teaching examples. In the drawings, the size and/or relative sizes of layers and regions may be exaggerated for clarity. Throughout the drawings and written description, like reference numerals refer to like or similar elements.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative termt, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. Hereinafter, the present invention will be explained in detail with reference to the accompanying drawings.

FIGS. 1, 4, 6 and 7 are cross-sectional views illustrating a DRAM device formed in accordance with various embodiments of the invention.

FIG. 1 is a cross-sectional view illustrating the formation of a preliminary dielectric layer on a semiconductor substrate.

Referring to FIG. 1, one or more isolation layer(s) (not shown) is formed in upper portion(s) of a substrate 100 (e.g., a silicon wafer) to define a plurality of active regions (not shown). The isolation layer may be formed, for example, using a shallow trench isolation (STI) process.

A preliminary dielectric layer 102 including an oxynitride is formed on the upper surface of the substrate 100 including the isolation layer(s) and the active region(s). The preliminary dielectric layer 102 may include silicon oxynitride.

In one embodiment of the invention, the preliminary dielectric layer 102 is formed by a plasma oxidation treatment and a first plasma nitridation treatment applied to the upper surface of the substrate 100. The plasma oxidation treatment and the first plasma nitridation treatment may be performed in-situ.

After the substrate 100 has been placed in a competent plasma chamber, a silicon oxide layer is formed on the substrate 100 by an oxidation treatment. During the oxidation treatment, the substrate 100 is exposed to an oxygen plasma including oxygen radicals to form the silicon oxide layer. The silicon oxynitride layer, which serves in the illustrated example as the preliminary dielectric layer 102, is then formed by application of a first nitridation treatment. During the first nitridation treatment, the silicon oxide layer on the substrate 100 is exposed to a nitrogen plasma including nitrogen radicals. The oxidation treatment and the first nitridation treatment may be performed by a direct plasma process (i.e., direct generation of plasma in the process chamber) dr a remote plasma process (i.e., remote generation of plasma then transported to the process chamber).

As is conventionally understood, a process chamber adapted to the execution of a direct plasma process may generally include a plasma chamber, a susceptor, a gas provision unit, and a radio frequency (RF) electrode. The susceptor may be disposed in the plasma chamber and is typically adapted to support the substrate 100. The gas provision unit provides a desired reaction gas including (e.g.,) various oxide and/or nitride gases, etc., into the plasma chamber. The RF electrode is disposed over the susceptor and is electrically connected to an RF power source in order to convert the reaction gas in the plasma chamber into a plasma.

As is also conventionally understood, a process chamber adapted to the execution of a remote plasma process may include a plasma chamber, a susceptor, a gas provision unit and a remote plasma generator. Again, the susceptor is disposed in the plasma chamber and supports the substrate 100. The gas provision unit provides the reaction gas to the plasma chamber. The remote plasma generator is electrically connected to a mechanism for applying microwave or RF energy to a reaction gas in order to convert the reaction gas into a plasma state.

The plasma oxidation treatment may be performed using any competent reaction gas including oxygen, hydrogen, etc. Additionally, an inert gas such as argon, helium, xenon, krypton, etc. may be used as a carrier gas, a pressure control gas, or an ignition gas. In one more specific embodiment, the plasma oxidation treatment may be performed at a temperature ranging between about 350° C. to about 900° C. under a pressure ranging from about 10 mTorr to about 10 Torr.

Similarly, the first plasma nitridation treatment may be performed using a competent reaction gas including, for example, ammonia, nitrogen, etc. Additionally, an inert gas such as argon, helium, xenon, krypton, etc. may be used as carrier gas, a pressure control gas, or an ignition gas. The first plasma nitridation treatment may be performed under similar temperature and pressure conditions as the plasma oxidation treatment.

Alternatively, after forming a silicon oxide layer on the substrate 100 by a plasma oxidation treatment as described above, a silicon oxynitride layer may be formed by a first plasma nitridation treatment in-situ. Here, nitrogen ions from a nitrogen plasma may be implanted into upper surface portions of the substrate 100 by applying a bias voltage to the stusceptor.

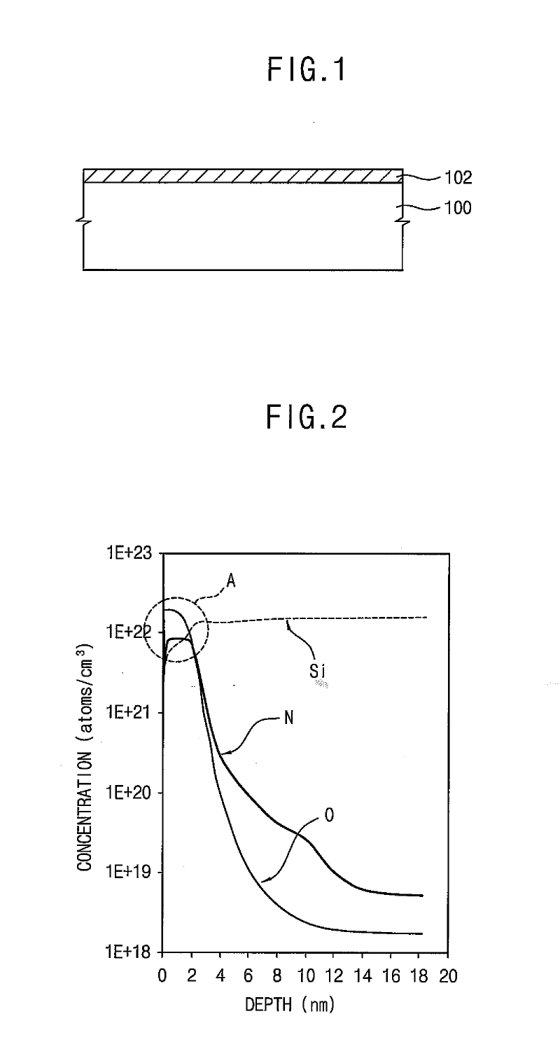

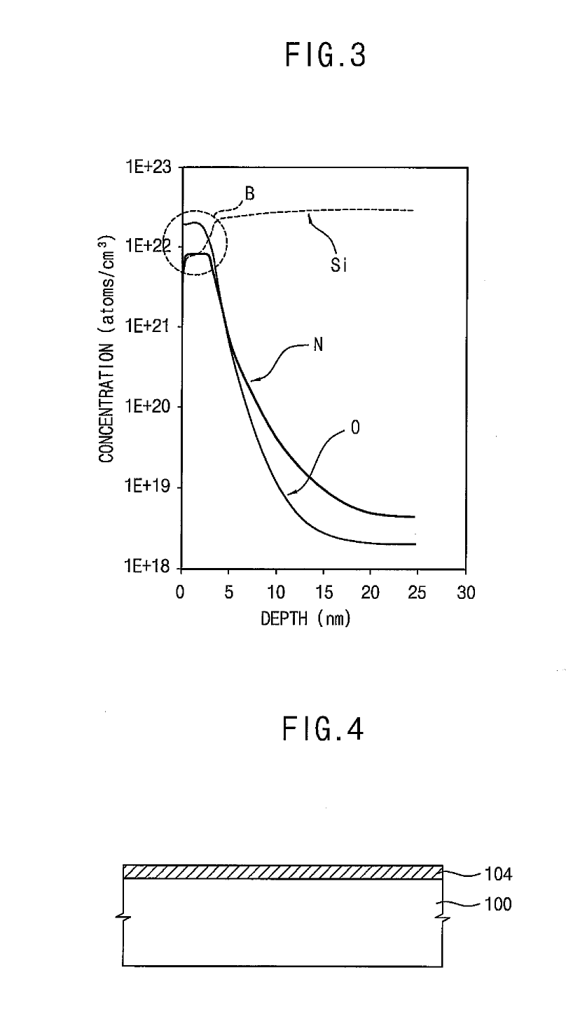

In one embodiment of the invention, the nitrogen concentration of a silicon oxynitride layer formed by a plasma oxidation treatment and an in-situ first plasma nitridation treatment was measured using a secondary ion mass spectroscopy (SIMS). The results of this measurement are shown in FIGS. 2 and 3.

FIG. 2 is a graph illustrating a nitrogen concentration profile for a silicon oxynitride layer formed by a plasma oxidization treatment and an in-situ first plasma nitridation treatment. FIG. 3 is a graph illustrating a nitrogen concentration profile for a silicon oxynitride layer formed by a plasma oxidization treatment and an in-situ first plasma nitridation treatment using a bias voltage. As may be seen from FIGS. 2 and 3, the concentrations of nitrogen (N), oxygen (O) and silicon (Si) are illustrated as a function of depth into the silicon oxynitride layer.

Referring to FIGS. 2 and 3, the silicon oxynitride layer has a relatively uniform nitrogen concentration in depth regions highlighted by portions A and B of the respective graphs. Additionally, relatively high concentrations of oxygen are apparent in the silicon oxynitride layer in these portions of the silicon oxynitride layer. That is, oxygen replaced by nitrogen is significantly present in the silicon oxynitride layer before performing a second plasma nitridation treatment.

It should be noted that formation of the preliminary dielectric layer 102 may alternately be accomplished by simultaneously performing a plasma oxidation treatment and a first plasma nitridation treatment on the substrate 100 using a mixed plasma including oxygen and nitrogen radicals. A bias voltage may be applied to the susceptor supporting the substrate 100 when the plasma oxidation treatment and the first plasma nitridation treatment are simultaneously performed. That is, oxygen ions and nitrogen ions may be implanted in the substrate 100 from a mixed plasma by applying the bias voltage to the susceptor.

FIG. 4 is another cross-sectional view illustrating a gate dielectric layer 104 formed on the substrate 100. The gate dielectric layer 104 may be formed on the substrate 100 by application of a second plasma nitridation treatment to the substrate 100 on which the preliminary dielectric layer 102 has been formed.

The nitrogen concentration of the gate dielectric layer 104 is increased by the second plasma nitridation treatment. The nitrogen concentration of the gate dielectric layer 104 may be sufficiently increased by a substitution reaction between nitrogen radicals and the oxygen ions present in the preliminary dielectric layer 102.

The gate dielectric laydr 104 having an increased nitrogen concentration will exhibit improved capacitance characteristics because the gate dielectric layer 104 has a dielectric constant greater than the conventionally formed silicon oxynitride layers. Additionally, the gate dielectric layer 104 will provide better immunity to leakage current as compared with conventionally formed silicon oxynitride layers. The gate dielectric layer 104 better inhibits impurities diffusion into the substrate 100. Finally, the gate dielectric layer 104 improves electron mobility within the constituent semiconductor device, such that operating speed and a reliability are improved.

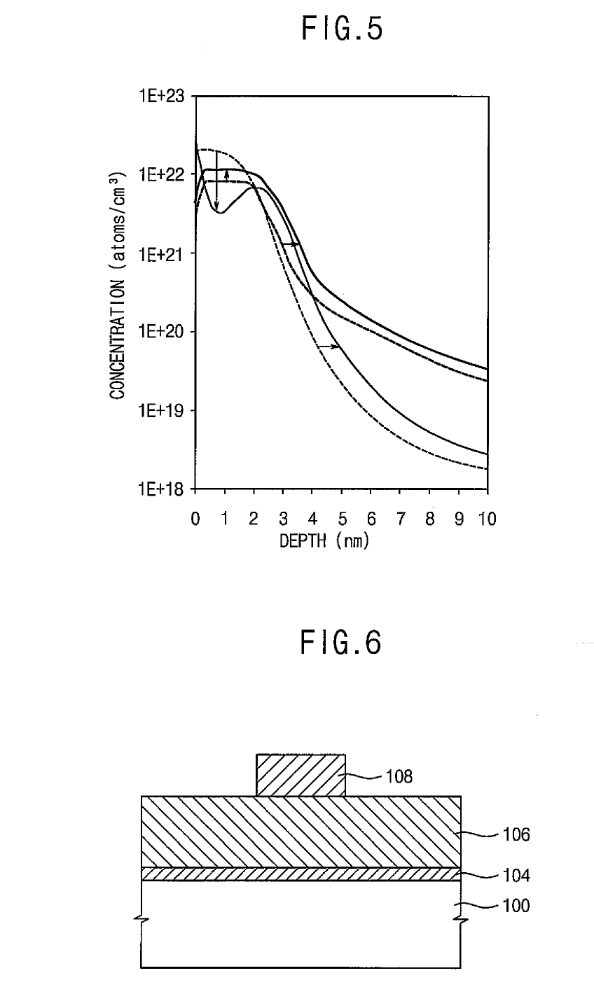

Changes in concentrations of oxygen and nitrogen between the preliminary dielectric layer 102 and the gate dielectric layer 104 were measured using a secondary ion micro-scope (SIMS). These results are shown in FIG. 5.

FIG. 5 is a graph illustrating the concentration profiles of nitrogen and oxygen in the preliminary dielectric layer 102 and the gate dielectric layer 104. In FIG. 5, the concentrations of nitrogen and oxygen are as a function of depth into these respective layers.

Referring to FIG. 5, the nitrogen concentration in the gate dielectric layer 104 is increased, while the oxygen concentration in the gate dielectric layer 104 is decreased due to a substitution reaction between nitrogen radical and oxygen in the preliminary dielectric layer 102. The nitrogen concentration of the gate dielectric layer 104 may be sufficiently increased by the substitution reaction because the preliminary dielectric layer 102 includes a sufficient amount of oxygen.

In the illustrated embodiment of the invention, after the second plasma nitrogen treatment is performed, a heat treatment for curing defects generated when the gate dielectric layer 104 is formed, and for condensing the gate dielectric layer 104 may be additionally (and optionally) performed. The heat treatment may be performed at a temperature ranging from about 800° C. to about 1100° C. in an atmosphere including nitric oxide (NO) gas, nitrous oxide (N2O) gas, ammonia (NH3) gas, nitrogen (N2) gas, oxygen (O2) gas, etc. Alternatively, the heat treatment may be performed in an atmosphere of an inert gas such as argon (Ar) gas, helium (He) gas, etc.

FIG. 6 is a cross-sectional view illustrating a conductive layer 106 and a mask 108 formed on the gate dielectric layer 104 in accordance with an embodiment of the invention.

Referring to FIG. 6, the conductive layer 106 and a mask layer (not shown) are sequentially formed on the gbte dielectric layer 104. The mask layer may be partially removed by an anisotropic etching process using a photoresist pattern (not shown) as an etching mask to form the mask 108.

The conductive layer 106 may be formed from polysilicon doped with impurities and may be formed by a low pressure chemical deposition process (LPCVD) using a source gas including silicon. In one more specific example, the conductive layer 106 is formed using an LPCVD process with an impurity gas including silane (SiH4) gas, phosphorus (P), boron (B), etc. at a temperature of about 580° C. to about 620° C. Alternatively, the conductive layer 106 may be formed by doping impurities into a polysilicon layer after forming the polysilicon layer using silane (SiH4) gas. The impurities may be doped into the polysilicon layer by an impurity diffusion process or an ion implantation process.

The mask layer may be formed from a silicon nitride and may be formed using an LPCVD process with a source gas including silicon and a reaction gas including nitrogen.

The photoresist pattern may be formed by a common photolithography process, and may be removed by an ashing process and/or a strip process after forming the mask 108.

FIG. 7 is a cross-sectional view illustrating a transistor formed on the substrate 100 in accordance with an embodiment of the invention.

Referring to FIG. 7, a gate structure including the mask 108, a gate electrode 110 and a gate dielectric layer pattern 112 may be formed on the substrate 100 using an anisotropic etching process selective with respect to the mask 108.

A gate spacer 114 may be formed on sidewalls of the gate structure, and source/drain regions 116 may be formed in proximate upper surface portions of the substrate 100 adjacent to the gate structure, thereby completing a semiconductor device, such as a field effect transistor (FET).

The gate spacer 114 may include silicon nitride, silicon oxide, etc. The gate spacer 114 may be formed by forming an insulation layer on the substrate 100 to cover the gate structure and partially removing the insulation layer to expose an upper face of the substrate 100. The insulation layer may include silicon nitride or silicon oxide.

The source/drain regions 116 may be formed by an ion implantation process after or before formation of the gate spacers 114. Alternatively, source/drain regions 116 may be formed with a lightly-doped-drain (LDD) structure including a lightly doped region and a heavily doped region by performing a selective ion implantation process before and after the formation of the gate spacers 114.

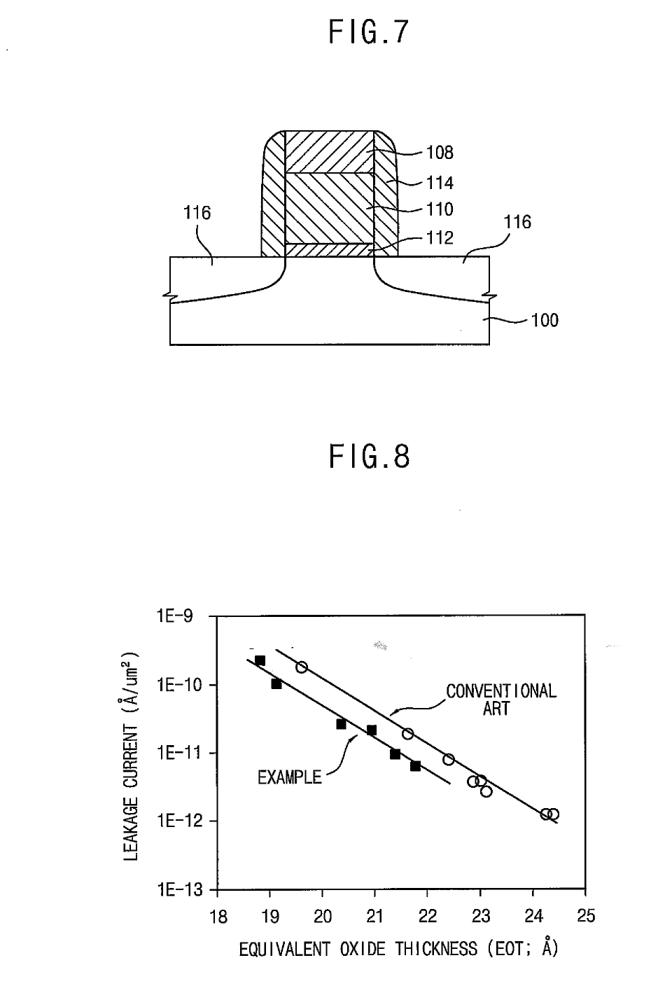

FIG. 8 is a graph comparing leakage currents for a conventional gate dielectric layer and a gate dielectric layer formed in accordance with an example embodiment of the invention. In FIG. 8, gate leakage currents are shown with respect to an equivalent oxide thickness (EOT) for the conventional gate dielectric layer and the gate dielectric layer formed in accordance with an example embodiment of the invention.

A plurality of first gate dielectric layers was formed as follows. A thermal oxidation process was performed on a substrate including silicon to form a preliminary dielectric layer including silicon oxide. A first plasma nitridation treatment was performed on the preliminary dielectric layer to form a first gate dielectric layer on the semiconductor substrate.

The plurality of the first gate dielectric layers was formed by the above-described conventional method.

A plasma oxidation treatment and a second plasma nitridation treatment were performed on the substrate in-situ to form a preliminary dielectric layer including silicon oxynitride, and a second plasma nitridation treatment was performed on the preliminary dielectric layer to form a second gate dielectric layer.

A plurality of the second gate dielectric layers was formed by the above-described method in accordance with an example embodiment of the invention.

As shown in FIG. 8, the second gate dielectric layer formed by the method in accordance with an example embodiment of the invention exhibits improved leakage current characteristics compared with the first gate dielectric layer formed using the conventional method.

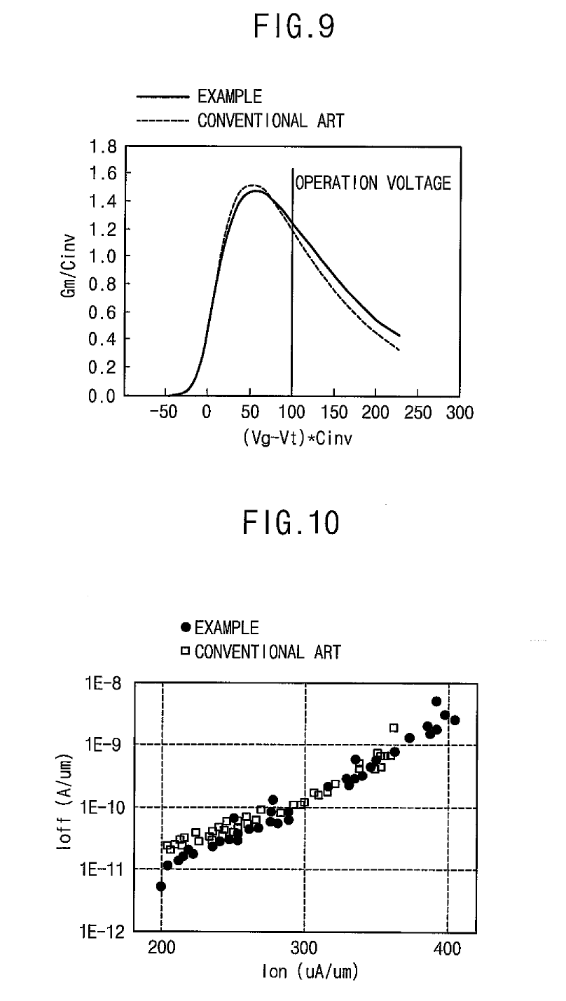

FIG. 9 is a graph comparing transconductances for semiconductor devices including a conventional gate dielectric layer and a gate dielectric layer formed in accordance with an example embodiment of the invention.

When the transconductance (i.e., a field effect mobility) of an n-channel metal-oxide field-effect transistor (nMOSFET) having a conventional gate dielectric layer (hereinafter referred to as “a first transistor”) is compared with the transconductance of an nMOSFET having a gate dielectric layer formed in accordance with an embodiment of the invention (hereinafter referred to as “a second transistor”), the second transistor transconductance is generally higher than the first transistor transconductance in the presence of similarly applied operating voltages, as shown in FIG. 9. The term “Cinv” represents inversion-layer capacitance in FIG. 9.

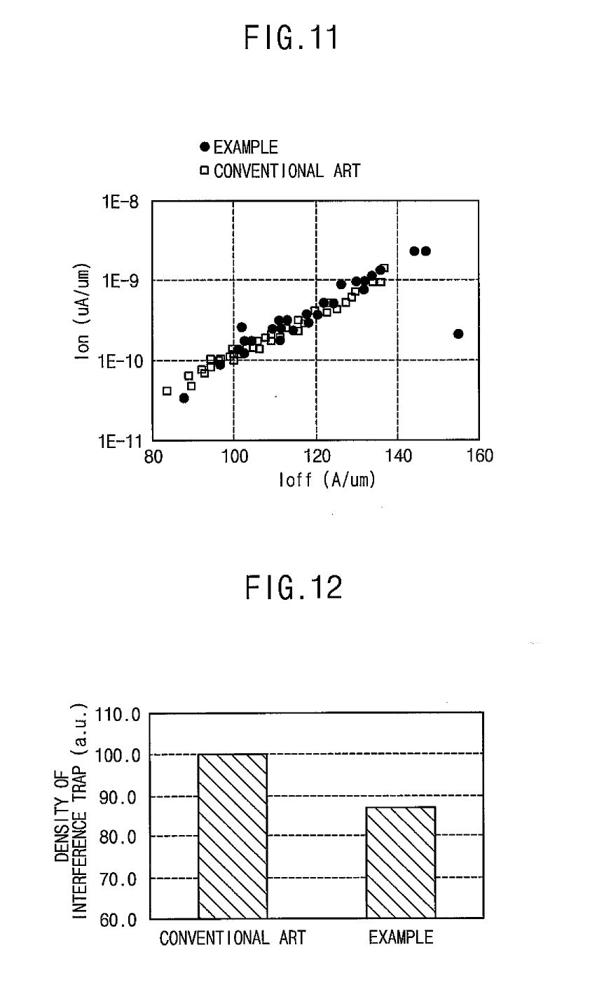

FIGS. 10 and 11 are respectively graphs comparing ON-currents versus OFF-currents for a conventional semiconductor device and a semiconductor device formed in accordance with an example embodiment of the invention. FIG. 12 is a graph illustrating the density of interface trap (DIT) for the conventional semiconductor device and the semiconductor device formed in accordance with an example embodiment of the invention. (Here again, the terms “first and second transistor” are used in reference).

When ON-currents and OFF-currents for the first and second transistors were measured, the second transistor had an EOT thicker than that of the first transistor as shown in FIG. 1, whereas the ON-current and OFF-current of the second transistor was similar to that of the first transistor. When ON-currents and OFF-currents of a first (p-channel) metal-oxide field-effect transistor (pMOSFET) formed using a conventional method and a second pMOSFET formed in accordance with an example embodiment of the invention were measured, the first pMOSFET had an EOT thicker than that of the second pMOSFET. However, the ON-current and OFF-current of the second pMOSFET were similar to those of the first pMOSFET, as shown in FIG. 11.

Additionally, the second transistor had a DIT decreased by 13% compared with that of the first transistor as shown in FIG. 12.

According to the foregoing embodiments of the invention, a gate dielectric layer may be formed on a semiconductor substrate by a second plasma nitridation treatment of a preliminary dielectric layer including silicon oxynitride after forming the preliminary dielectric layer having a relatively higher oxygen concentration by a plasma oxidation treatment and a first plasma nitridation treatment on the semiconductor substrate.

The gate dielectric layer may have a nitrogen concentration higher than that of a conventional gate dielectric layer. Thus, the gate dielectric layer may decrease a leakage current, and prevent diffusion of impurities into the channel region from the gate electrode. Additionally, the gate dielectric layer may increase ON-current when applied with an operating voltage and decrease density of interface trap (DIT).

As a result, a semiconductor device having the gate dielectric layer formed in accordance with an embodiment of the invention will exhibit improved operating speed and greater reliability with reduced power consumption.

The foregoing embodiments are illustrative of the present invention and should not be construed as limiting thereof. Although several illustrated embodiments have been described, those skilled in the art will readily appreciate that many modifications are possible without materially departing from the novel teachings and advantages of the present invention. Accordingly, all such modifications are intended to be included within the scope of this invention as defined in the claims.

What is claimed is:

1. A method of manufacturing a semiconductor device in a process camber, the method comprising:
forming a preliminary dielectric layer including oxynitride on a substrate by performing a plasma oxidation treatment and a first plasma nitridation treatment, wherein the preliminary dielectric layer has a substantially uniform nitrogen concentration profile to a defined depth; and
forming a dielectric layer from the preliminary dielectric layer by performing a second plasma nitridation treatment, wherein the nitrogen concentration of the dielectric layer is higher than that of the preliminary dielectric layer.

2. The method of claim 1, wherein performing the plasma oxidation treatment and the first plasma nitridation treatment is done in-situ.

3. The method of claim 2, wherein the process chamber comprises a susceptor supporting the substrate, and performing the first plasma nitridation treatment comprises applying a bias voltage to the susceptor.

4. The method of claim 1, wherein the plasma oxidation treatment and the first plasma nitridation treatment are simultaneously performed.

5. The method of claim 4, wherein the process chamber comprises a susceptor supporting the substrate, and simultaneously performing the plasma oxidation treatment and the first plasma nitridation treatment comprises applying a bias voltage to the susceptor.

6. The method of claim 1, wherein the plasma oxidation treatment is performed using a reaction gas including oxygen and hydrogen.

7. The method of claim 1, wherein the plasma oxidation treatment is performed using a reaction gas and an inert gas, the reaction gas including oxygen and hydrogen, and the inert gas being adapted to control pressure or ignite plasma.

8. The method of claim 1, wherein the plasma nitridation treatment is performed using a reaction gas including nitrogen and ammonium.

9. The method of claim 1, wherein the plasma nitridation treatment is performed using a reaction gas and an inert gas, the reaction gas including nitrogen and ammonium, and the inert gas being adapted to control pressure or ignite plasma.

10. The method of claim 1, further comprising:
after forming the dielectric layer, performing a heat treatment to cure defects and condense the dielectric layer.

11. The method of claim 1, further comprising:
forming a conductive layer on the dielectric layer;
forming a mask on the conductive layer; and
forming a gate structure including a dielectric layer pattern and a gate electrode.

12. The method of claim 11, further comprising:
forming a gate spacer on sidewalls of the gate structure.

13. The method of claim 11, further comprising:
forming source/drain regions proximate the gate structure in upper portions of the substrate.
